(19) United States
(12) Patent Application Publication
(10) Pub. No.: US 2018/0269081 A1
(43) Pub. Date: Sep. 20, 2018

(54) SYSTEM AND METHOD FOR STATUS-DEPENDENT CONTROLLING OF A SUBSTRATE AMBIENT IN MICROPROCESSING

(71) Applicant: GLOBALFOUNDRIES Inc., Grand Cayman (KY)

(72) Inventors: Boris Bayha, Dresden (DE); Martin Trentzsch, Netzschkau (DE)

(21) Appl. No.: 15/463,478

(22) Filed: Mar. 20, 2017

(51) Int. Cl. H01L 21/677; H01L 21/67

(52) U.S. Cl. CPC H01L 21/6773; H01L 21/67248; H01L 21/67769

(57) ABSTRACT

The present disclosure provides systems and techniques in which an ambient may be controlled on the basis of a current status of a micro-processed substrate so as to maintain the status within predefined limits. In illustrative embodiments, the substrate may be stored in an ambient, for which temperature and/or contents of one or more gaseous species may be controlled so as to reduce the change of status. Consequently, in particular, queue times may be significantly prolonged, thereby imparting superior flexibility to scheduling the overall process flow in a complex manufacturing environment.

### BACKGROUND

### 1. Field of the Disclosure

Generally, the present disclosure relates to systems and methods used for fabricating products, including features of dimensions of micrometers and significantly less, such as semiconductor devices and the like, wherein, starting from respective substrates in an initial status, a plurality of processes are performed in order to provide the substrates or any products obtained therefrom with a desired final manufacturing status.

### 2. Description of the Related Art

Products, including individual features of dimensions in the micrometer range and significantly less, are nowadays produced in highly complex automated facilities, in which a plurality of process tools are provided in a highly organized manner in order to perform all of the processes and provide and/or prepare the materials required for finishing the products under consideration at least to a desired manufacturing status. In the context of this application, any products, including certain features or components of dimensions in the order of micrometers and significantly less, will be referred to as micro-processed products and any manufacturing processes involved in fabricating any such products are referred to as micro-processing, irrespective of whether some of these processes may actually involve the generation of tiny features or may be applied in a more or less global manner, when, for instance, one or more material layers are formed above an entire substrate without restricting the deposition of the one or more material layers to device areas of micrometer dimensions. Similarly, any other related processes, such as cleaning processes, which may frequently be applied to a substrate as a whole, may be considered as a part of the micro-processing of respective substrates, since any of these globally applied processes may, nevertheless, provide the preconditions for the further processing of the substrates.

In modern facilities for producing micro-processed products, such as semiconductor facilities for producing integrated circuits of any type, facilities for forming micro-optical devices, micro-mechanical devices, or any type of mixture of any of these products, including feature sizes of a few micrometers and significantly less, a plurality of processes have to be performed in a certain sequence, wherein some of specific types of processes may have to be repeatedly applied to the respective products, for instance when considering lithography processes, in order to sequentially add material and/or structural components to the product under consideration. Moreover, since typically many types of different products may be produced, each of which may require a different process recipe, a plurality of substantially equivalent process tools may be provided and may be operated in parallel, possibly on the basis of different process recipes, in order to insure sufficient flexibility in processing different types of products and/or increasing overall throughput for a specific step of the entire micro-processing sequence.

For example, in sophisticated semiconductor facilities for producing semiconductor devices, such as integrated circuits and the like, a plurality of lithography tools in combination with associated process modules for pre-processing and post-processing may be present in the semiconductor facility in order to comply with the various requirements in terms of throughput, process flexibility, and the like. Similarly, a plurality of deposition tools for forming the various materials required in the respective states of a processed product may be available, wherein different process recipes may also be typically implemented so as to comply with the overall requirements in terms of different product types and the like. Furthermore, during various stages of the overall micro-processing, methodology steps have to be implemented in the overall process sequence so as to monitor process quality of the various processes. From these measurement data, various process parameters may be readjusted so as to maintain the respective process outputs within certain specific target ranges. Since even micro-processed products of moderate complexity may require a relatively high number of individual process steps, for instance, several hundred process steps may be required for integrated circuits of average complexity, it is evident that a more or less complex schedule may be typically required for appropriately processing the respective products or substrates at each specific manufacturing status in an appropriately configured process tool on the basis of the appropriate process recipe so as to optimize overall throughput.

To this end, a corresponding supervising control system may usually be used for obtaining the relevant process data, such as the status of the respective process tools, workload of these process tools, measurement data, and the like, in order to control overall flow of substrates within the manufacturing environment. Due to process-related waiting times and/or in view of maintenance activities for the various process tools, which may represent planned or non-planned down times of the process tools, additional idle times for the substrates may occur at various stages of the overall process flow. Any such times, which may also be referred to as “queue times,” may have a significant influence, not only on the overall throughput of the manufacturing environment under consideration, but also on the process quality itself, since, for instance, a varying queue time of products of basically the same type may, nevertheless, result in a different status of the corresponding products prior to the further processing thereof, which, in turn, may result in a different process output, thereby possibly generating products of reduced quality or products which fail to meet the minimum required quality standards.

With reference to FIG. 1, a corresponding prior art manufacturing environment may be described in a highly schematic manner in order to more clearly demonstrate the problems involved in the production of micro-processed substrates or products.

FIG. 1 schematically illustrates one example of a prior art manufacturing environment 180, which may comprise a plurality of process tools 181A, 181B, 181C, 181N, which are to represent the plurality of process tools as may be required for obtaining a micro-processed product having a specified manufacturing status. For example, the process tools 181A-181N may comprise process tools for depositing any type of material as required for the micro-processed products, such as tools for epitaxial growth of specific semiconductor materials, tools for depositing any type of dielectric materials, tools for depositing semiconductor materials in a non-crystalline state, tools for depositing highly conductive materials, and the like. Furthermore, these process tools may include tools for performing lithography processes and associated processes required prior to actually exposing the products to radiation. For example, appropriate cleaning processes may be performed in combination with the deposition of appropriate radiation-sensitive materials and the like, possibly associated with a heat treatment so as to prepare the substrates for a subsequent actual exposure process. Similarly, post-lithography processes may be performed on the basis of development techniques, possibly associated with heat treatments and the like.

Furthermore, the process tools 181A-181N may include process tools for performing isotropic and anisotropic etch processes, ion implantation processes, and the like, which may basically be designed so as to appropriately “pattern” previously provided material layers, possibly in accordance with any previously performed lithography process, which may be used to provide respective patterning masks in the form of removable or permanent structured material layers.

It should be appreciated that, as discussed above, typically, a plurality of process tools of basically the same category may be present in the manufacturing environment 180 so as to enhance overall throughput and also provide superior flexibility when different process recipes may have to be applied for different types of substrates. Consequently, when referring to a plurality of substrates 184 to be processed in the process tools 181A-181N, it should be understood that these substrates 184 may have to be processed on the basis of different process recipes and that even substrates of the same type to be processed in accordance with the same process recipe may actually be processed by different process tools at different stages of the overall process flow.

Moreover, as also discussed above, the manufacturing environment 180 may typically comprise a plurality of measurement tools 182A, 182B, 182C, 182N in order to appropriately monitor the process quality of the various process tools. It should be appreciated that a corresponding measurement tool or block of measurement tools may not necessarily be provided at every stage of the entire process flow within the environment 180 as long as sufficient coverage of the overall process flow may be achieved by the measurement tools 182A-182N. Typically, a supervising control system 183 may be provided so as to receive measurement data, tool-related information, such as planned downtimes, information on specific events, such as non-planned downtimes of specific tools, and the like. On the basis of the information received from the manufacturing environment 180, the supervising control system 183 may control, at least to a certain degree, the overall flow of substrates 184 within the environment 180 so as to maintain overall throughput and process quality at a high level. To this end, upon detecting specific events, such as a downtime of a process tool, certain substrates 184 may be rerouted, for instance, for circumventing the non-functional process tool and the like, if these substrates have been given a superior priority compared to other substrates. In other cases, the current status of the manufacturing environment 180 may be continuously monitored and a corresponding process flow may be appropriately adapted so as to optimize utilization of available resources in the environment 180.

Irrespective of the efficiency of the supervising control system 183, the scheduling of the substrates 184 may, nevertheless, result in specific queue times during the processing of the substrates. For example, some queue times may be necessary to establish a certain status of processed substrates during certain stages of the overall process flow. For instance, the state of a processed substrate may need to reach a specific equilibrium when, for instance, a slow cooling down of a previously heated substrate may be required and the like. Other queue times may be basically caused by the limited resources in terms of process tools and measurement tools, since, for instance, a respective measurement process may take a certain time, which may be longer compared to the actual production process that has to be monitored on the basis of the measurement process under consideration. For example, if the process performed by the process tool 181A requires process monitoring by the measurement tool 182A, it may be necessary to transport the respective substrates to the measurement tool 182A and perform the measurement process so as to provide the respective measurement data to the control system 183. Consequently, at least for the substrates subjected to the measurement process, a certain delay or queue time may be generated, depending on the number of substrates to be measured, the number of measurement tools available and the duration of the measurement process itself. Moreover, even the transport of the substrates may contribute to the overall queue time. In addition to these system-specific queue times, which may be caused by the inherent structure of the manufacturing environment 180 and the respective process recipes used for the production process and the measurement, other contributions to queue times may occur due to maintenance activities and, in particular, due to non-planned downtimes of one or more of the process tools 181A-181N and/or the measurement tools 182A-182N.

Since respective queue times at specific stages of the overall process flow, i.e., at certain manufacturing statuses of the corresponding substrates 184, may not only negatively affect the overall throughput, but also process quality, at least at some stages the queue times may have to be carefully monitored so as to not exceed a previously determined length in order to at least reduce the influence on the finally obtained process quality. One prominent example for having to maintain queue time of substrates within a specific range is the formation of sophisticated dielectric materials, the characteristics of which may be appropriately adapted by incorporating a specific species. For example, when forming sophisticated dielectric materials for capacitive structures, such as gate electrodes of transistors, capacitors and the like, the final characteristics of the product significantly depend on the characteristics of the corresponding dielectric material.

For example, it may be assumed that the process tool 181C or any process tool equivalent thereto may be configured to form a dielectric layer and/or perform a surface treatment on a previously formed dielectric layer so as to adjust the desired characteristics of a dielectric material. To this end, one or more substrates 184 may be processed so as to receive a layer of dielectric base material 185, which may be provided above the entire surface area of the substrates 184 or which may be formed on specific surface areas that require a sophisticated dielectric material having well-tuned material characteristics. To this end, in the process tool 181C or any process tool in a previous stage of the overall process sequence, the layer 185 may be formed, for instance, on the basis of oxidation, deposition, chemical interaction and the like, depending on the material characteristics to be provided and/or the specific process recipe to be implemented.

As is well known, silicon-based semiconductor devices may frequently require a silicon oxide-based material in order to provide a dielectric base material for highly sophisticated products, such as gate electrode structures, capacitive structures and the like. To this end, the capacitance of the dielectric layer 185 is substantially determined by the material composition, such as the stoichiometric ratio of, for instance, silicon and oxygen species, any additional trace species, such as hydrogen and the like, and the density of the dielectric material, which may also significantly depend on the manufacturing process applied upon forming the dielectric base material 185. Moreover, a further critical parameter is the respective thickness of the layer 185, since the capacitance typically depends on the material characteristics and the distance of respective electrodes, i.e., the thickness of the dielectric material separating the electrodes for a given area of the capacitive structure under consideration. Since the formation of the dielectric base material 185 may usually require well-controlled process conditions, which may be adjustable with superior accuracy on the basis of materials for forming a silicon oxide material, a subsequent treatment may be frequently carried out so as to adjust the finally desired material composition and thus the final target capacitance.

To this end, an appropriate species 186, such as nitrogen, may be incorporated so as to finely tune the characteristics of the material layer 185. For this purpose, a plurality of well-established process techniques are available, such as establishing a plasma ambient or any other gaseous nitrogen-containing ambient with specified temperature conditions in order to incorporate a specified fraction of the species 186 into the base material layer 185. For example, a silicon oxide base material, including a certain proportion of nitrogen, may result in increased capacitance per area unit, thereby resulting in a reduced electrically equivalent thickness compared to a pure silicon oxide layer without actually affecting the physical thickness thereof. That is, for a given physical thickness of the base layer 185, increased capacitive coupling may be achieved by incorporating a certain fraction of nitrogen so that the electrically equivalent thickness is reduced while the physical thickness, which substantially determines the leakage behavior of the dielectric material for a given material composition, is basically maintained. Therefore, performance of circuit elements, such as field effect transistors, including a portion of the layer 185, capacitors and the like, may critically depend on the outcome of the process in the tool 181C, and any variation of the process result may, therefore, directly translate into a corresponding variation of device performance of a final product.

As discussed above, in a subsequent process, for instance, performed in the process tool 181N, which may represent the immediately next station of the products 184, a further material layer 187, for instance in the form of metal-containing material, highly doped semiconductor material, non-doped semiconductor material, or any combination thereof, may be deposited as required in accordance with the overall device architecture. For example, the material 187 may include additional dielectric materials, possibly in the form of metal-containing materials, so as to further adjust the overall capacitive behavior of base material 185, while, in other cases, the layer 187 may include any appropriate electrode material, such as polysilicon, silicon/germanium, germanium and the like, as may be required for more or less sophisticated gate electrode structures. Upon depositing the material layer 187, typically the material characteristics of the layer 185 may be conserved, at least in terms of out-diffusion of the species 186 previously incorporated into the layer 185. For example, upon depositing a polysilicon material on the layer 185, the surface area available for any interaction with the ambient atmosphere may be reliably covered, thereby “freezing” the proportion of species 186 incorporated in the layer 185.

As discussed above, in an actual process flow within the manufacturing environment 180, a certain queue time is typically also involved in forming the layer 185, incorporating the species 186 and finally covering the resulting layer 185 by the additional layer 187. Queue times may be associated with any unavoidable, non-planned delays due to down times of process tools and the like, while additional queue time contributions may also result from the normal scheduling within the environment 180, as already discussed above. During any queue times, the substrates involved may typically be stored in respective containers, such as front-opening unified pots (FOUP), which may typically be used for transporting and storing the substrates 184 within the manufacturing environment 180. Frequently, in particular, the storage of substrates having a certain substrate status due to the preceding micro-processing may be stored and await further processing by being exposed to the clean room ambient, which has a specified gas composition and temperature. Although this clean room ambient is precisely controlled so as to maintain predefined conditions, in particular, in terms of gas composition, temperature and, in particular, impurity particles, it turns out that nevertheless the queue time may have a significant influence on the final characteristics of the layer 185 prior to depositing the layer 187, thereby also significantly influencing performance of the final products, as discussed above. Moreover, in sophisticated applications, frequently a tightly controlled nitrogen atmosphere may be established in the respective transport containers, as typically a nitrogen atmosphere is considered as an inert ambient having very low influence on the current status of a substrate. For this reason, it has been suggested to use a pure nitrogen atmosphere when storing substrates during critical queue times. Nevertheless, it turns out that, even in this case, the storage of substrates 184 having the status after the incorporation of the species 186 may also significantly depend on the overall storage time, i.e., queue time, thereby also contributing to significant performance variations of the final products.

Consequently, very restrictive queue time limitations may be typically set in advance and may be applied by the supervising control system 183 so as to reliably avoid exceeding the allowable range of queue times. As discussed above, however, the overall scheduling of the processing of the plurality of substrates 184 in the manufacturing environment 180 may, therefore, frequently result in the risk of significant queue time violation of the substrates 184 having the status after incorporating the species 186, which may only be resolved by delaying the processing of other substrates, thereby possibly also causing significant variations in substrate statuses of these delayed substrates and/or significantly reducing overall throughput of the manufacturing environment 180, since respective resources may have to be rescheduled.

In view of the situation described above, the present disclosure, therefore, relates to techniques for establishing appropriate conditions during the process flow of substrates in a manufacturing environment for micro-processed products, while avoiding, or at least reducing, the effects of one or more of the problems identified above.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is based on the concept that a change of state of a micro-processed substrate in a manufacturing environment may be more precisely maintained within predetermined limits by controlling the ambient of the substrate, in particular, when the processing thereof may be delayed. That is, according to the present disclosure, the status of a substrate having experienced a certain degree of micro-processing may be efficiently determined and may be correlated with a specific ambient for the substrate in order to reduce the influence of any queue times or other delays with respect to the further processing of the substrate under consideration. For example, the status of certain substrates corresponding to critical device features, such as sensitive dielectric materials, sensitive conductive materials and the like, may be determined and/or monitored so as to determine at least one ambient parameter of a controllable ambient that is established with respect to keep a change of status within specified limits, thereby possibly increasing an acceptable queue time for the substrate of the specified status. Providing an increased tolerance range for queue times of substrates or products of a specific manufacturing status may thus provide superior flexibility in scheduling a corresponding manufacturing environment, which may also directly translate into reduced overall manufacturing costs. On the other hand, for maintaining pre-established queue time tolerance ranges, a reduced variation of substrate status and thus a reduced variation of device performance of final products may be achieved.

In one illustrative embodiment of the present disclosure, a system is provided for temporarily storing substrates during micro-processing. The system includes a carrier configured to receive and hold one or more substrates in a controllable ambient, wherein the one or more substrates have a specific substrate status. The system further includes an ambient control unit that is operatively connected to the carrier and is configured to control the controllable ambient by adjusting one or more ambient-specific parameters in relation to the specific substrate status.

In a further illustrative embodiment disclosed herein, a method is provided, wherein the method includes determining a substrate status of one or more substrates in a specified stage of micro-processing of the one or more substrates. The method further includes adjusting at least one ambient-specific parameter of a controllable ambient of the one or more substrates in relation to the substrate status.

According to still a further illustrative embodiment disclosed herein, a system is provided for controlling an ambient of micro-processed substrates. The system includes a substrate carrier configured to receive one or more of the micro-processed substrates, wherein the micro-processed substrates comprise surface areas with a species that is subject to diffusion from the surface areas into an ambient confined by the substrate carrier. The system further includes an ambient control unit configured to control the ambient by adjusting at least one ambient-specific parameter of the ambient so as to maintain a level of diffusion of the species within a target range.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a manufacturing environment including a plurality of process tools and measurement tools for processing substrates on the basis of a micro-processing manufacturing regime;

FIG. 2 schematically illustrates a system for controlling an ambient of one or more substrates at a specific manufacturing status so as to maintain a change of the substrate status within specified limits according to illustrated embodiments;

FIG. 3 schematically illustrates a graph that depicts a variation of the electrically equivalent thickness of a sensitive dielectric material due to out-diffusion versus time to the next process step in accordance with illustrative embodiments; and

FIG. 4 schematically illustrates a graph that indicates a reduction of the change of equivalent thickness of a sensitive dielectric material versus queue time, when controlling temperature of an ambient of micro-processed substrates according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As discussed above, a restriction of queue times or any other time delays of a substrate having a specified substrate status, i.e., a specified status of micro-processing, may significantly affect the overall organization and scheduling in a complex manufacturing environment. Since the substrate status at specific stages of the manufacturing process may change when storing the respective substrates within the clean room ambient or even within pure nitrogen ambient, these techniques are less than desirable for enhancing overall productivity of a complex manufacturing environment.

For this reason, the present disclosure provides systems and methods in which a correlation may be determined so as to enable substrates with sensitive status to be stored in a controlled ambient that is established by taking into consideration the correlation between the substrate status and one or more ambient-specific parameters. The determination of a correlation between one or more ambient parameters or ambient-specific parameters and a given substrate status may include, in some illustrative embodiments, merely the information of the substrate status under consideration and one or more appropriate values for adjusting the one or more ambient parameters, thereby providing an efficient control mechanism, wherein appropriate parameter values may be determined in advance, for instance, on the basis of experiments, respective models of the variation of a substrate status with respect to a well-specified environment, measurement data, and the like.

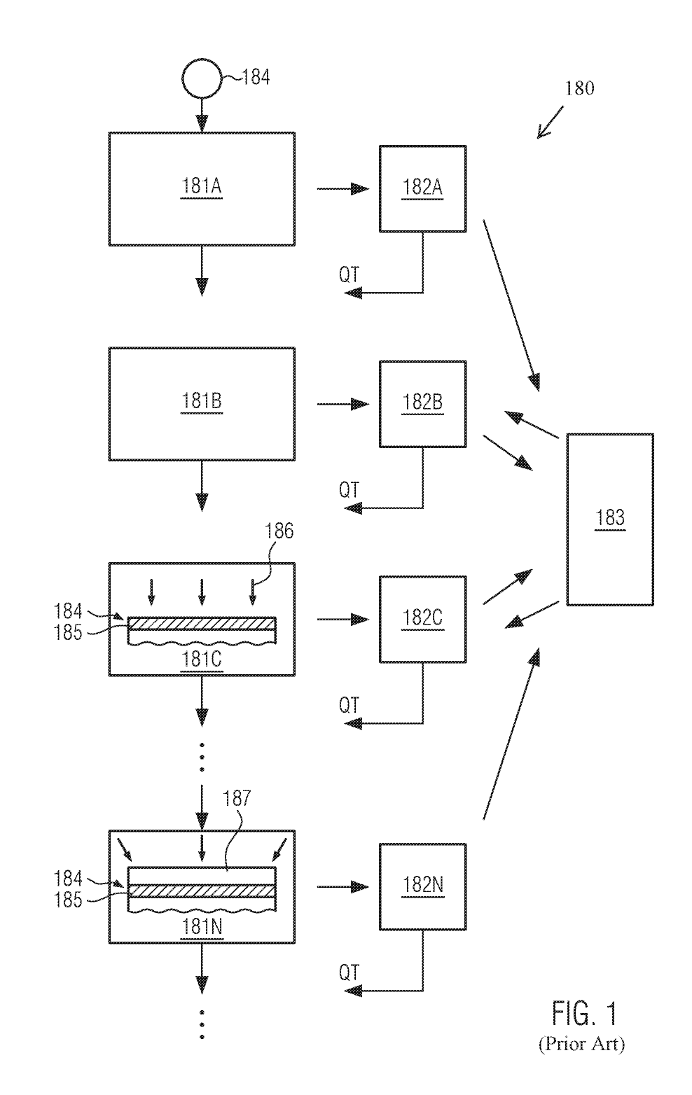

For example, as discussed above in the context of FIG. 1, sensitive dielectric materials may experience a variation of electrically equivalent thickness when exposed to well-defined environmental conditions, wherein any such changes of material characteristics may not be efficiently accommodated by the preceding process, since non-predictable queue times may, nevertheless, occur and therefore contribute to undesired variations of the respective substrate status under consideration. That is, when it is known that a typical increase of electrically equivalent thickness may be observed for a base silicon oxide layer having incorporated therein a nitrogen species, a corresponding increase of the nitrogen fraction during the process of incorporating the nitrogen species may not account for any non-predictable queue time variations between the nitrogen incorporation and the subsequent deposition of a gate electrode material. Therefore, according to the principles of the present disclosure, the substrate status may be obtained in accordance with well-established process recipes, while varying queue times prior to a subsequent process may be accommodated by controlling at least one ambient-specific parameter of a controllable ambient so as to appropriately affect the change of the substrate status, for instance, the electrically equivalent thickness of the dielectric material.

It should be appreciated that the control of the respective ambient may not only take into consideration non-predictable and predictable queue times of the substrate under consideration, but also any process variations of the preceding process, if a corresponding significant deviation from the target of the process output is detected. For example, it has been recognized by the inventors that the storage of a nitrogen-enriched silicon oxide layer, for instance, used for gate electrode structures and capacitors, may result in an increase of the electrically equivalent thickness of the material when exposed to the standard clean room environment. On the other hand, it has been observed that storage in a 100% nitrogen atmosphere, as may be frequently established in storage containers used in semiconductor facilities, may result in a reduction of the electrically equivalent thickness of the dielectric layer. Without intending to restrict the present application to a specific theory, it is, nevertheless, assumed that the nitrogen partial pressure in the ambient surrounding the substrate under consideration may have an effect on the diffusion behavior of the nitrogen species within the dielectric material. Therefore, the nitrogen fraction in the ambient surrounding the substrate under consideration may, therefore, provide an efficient mechanism for controlling the substrate status, i.e., in the present example, the electrically equivalent layer thickness, by adjusting the fraction of the nitrogen species within the ambient. In this case, a control of the electrically equivalent thickness of the dielectric layer may be performed in both direction, i.e., for increasing or decreasing the electrically equivalent layer thickness, depending on the initial and/or current substrate status.

That is, upon detecting a significant deviation in the direction of increased electrically equivalent thickness, a decreased nitrogen concentration may be established within the respective ambient, thereby resulting in a continuous increase of the electrically equivalent thickness during a respective queue time due to incorporation of nitrogen. In this case, upon occurrence of a non-predicted queue time, the corresponding ambient-specific parameter, for instance in this example, the nitrogen contents of the ambient, may be appropriately adapted, for instance, be increased so as to significantly increase the reduction of the electrically equivalent layer thickness. Similarly, when starting from an electrically equivalent thickness that is too low and a corresponding deviation amount is well within a standard queue time for the respective type of substrates, a corresponding reduced nitrogen concentration may be applied so as to continuously increase the electrically equivalent thickness by out-diffusion. In this case, the current status may also be monitored continuously or on a regular basis in order to enable a repeatedly performed adaptation of the respective ambient-specific parameter.

In other cases, other ambient-specific parameters may be determined, for instance, substrate temperature, which may also have a significant influence on the diffusion behavior of a species incorporated in a specific material portion of a substrate. It should be appreciated that the substrate temperature, which may be represented by the temperature at a specified substrate position or by the mean value of a plurality of temperatures at a plurality of different substrate positions, may be considered as an ambient-specific parameter, since the substrate under consideration will typically thermally interact with the surrounding ambient, thereby finally establishing, at least approximately, a thermal equilibrium state. For example, the controllable ambient surrounding the substrate under consideration may be adjusted to a specific ambient temperature, for instance, by providing heating/cooling units in direct contact with the substrates under consideration, radiation units, heating/cooling units for heating/cooling the gaseous atmosphere in the ambient, and the like, so as to finally adjust the corresponding substrate temperature via direct thermal conduction and/or convection and/or radiation. When considering temperature as an efficient ambient-specific parameter, and when referring to the above-mentioned example of controlling the electrically equivalent thickness of a dielectric material, by increasing the substrate temperature, a corresponding diffusion activity may be increased. On the other hand, by reducing the substrate temperature, the diffusion activity may be reduced, thereby also enabling an efficient adjustment of the desired substrate status, i.e., in this example, the electrically equivalent thickness of the dielectric material. In other cases, other “components” of the control ambient, such as an intensity profile of a specific portion of radiation, may be controlled so as to effectively influence the substrate status, wherein any such control may be performed in relation to the previously determined substrate state and/or in relation to a regularly or continuously determined substrate status so as to maintain the final substrate status within predefined limits substantially independent of a corresponding queue time.

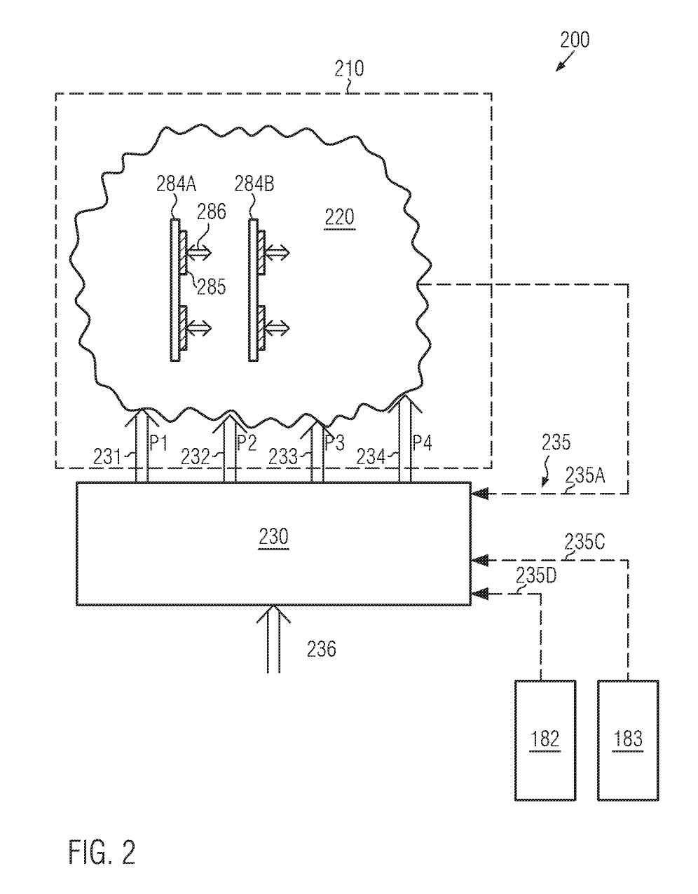

With reference to FIGS. 2-4, further illustrative embodiments will now be described in more detail, wherein reference may also be made to FIG. 1 when appropriate.

FIG. 2 schematically illustrates a system 200 that is configured to store one or more substrates 284A, 284B in a time period between two subsequent micro-processes, irrespective of whether transportation and/or a waiting time or queue time for the one or more substrates 284A, 284B is required. To this end, the system 200 may comprise a carrier 210 for receiving and holding the substrates 284A, 284B, wherein the carrier 210 may be further configured so as to enable the establishment of an ambient 220 that is controllable and that may, therefore, be controlled so as to comply with the requirements of the one or more substrates 284A, 284B in their respective manufacturing status. For example, in illustrative embodiments, the carrier 210 may be provided in the form of a transport container, such as an FOUP, which is frequently used for temporarily storing and transporting substrates in a manufacturing environment.

The system 200 may further comprise an ambient control unit 230 that is operatively connected to the ambient 220, for instance, by being mechanically coupled to the carrier 210 or by otherwise providing respective functional connections so as to enable the control of one or more ambient-specific parameters 231, 232, 233, 234 in relation to a specific status of the substrates 284A, 284B. For example, the ambient control unit 230 may comprise any appropriate hardware components for establishing a desired gaseous atmosphere within the ambient 220. It is to be understood that establishing a gaseous atmosphere may involve the supply of at least one, typically two or more gaseous species, for instance, nitrogen, oxygen, argon, helium and the like, wherein the respective pressure of each gaseous species may be controlled individually, thereby also controlling the total pressure of the gaseous atmosphere of the ambient 220. To this end, a respective supply, schematically indicated at 236, of any appropriate gaseous species may be provided and operatively attached to the ambient control unit 230, while, in other cases, permanent gas sources may be incorporated in the unit 230. Moreover, respective hardware components may also include valve systems or any other flow regulators required for establishing the desired mixture of gaseous species within the ambient 220. For convenience, any such well-known hardware components are not illustrated in FIG. 2. Similarly, the control of ambient-specific parameters, such as the parameters 231-234 may, in some illustrative embodiments, also involve the provision of respective sensors so as to obtain measurement data in the ambient control unit 230, which may, in turn, be used for appropriately activating respective hardware components, such as valves, gas flow regulators and the like.

Furthermore, the ambient control unit 230 may receive information on the status of the substrates 284A, 284B to be stored in the ambient 220, wherein this information is generally denoted as 235. As already discussed, the status of the one or more substrates 284A, 284B may be represented by one or more values indicating the state of processing and/or a condition of one or more components of the substrates 284A, 284B. For example, the substrates 284A, 284B in the manufacturing stage under consideration may have a surface area 285, for instance, represented by a portion of a material layer, which may interact, as indicated by 286, with the controllable ambient 220 by one or more interaction mechanisms. For instance, the interaction 286 may involve diffusion of a species present in the surface areas 285 into the ambient 220, wherein, without intending to restrict the present application to the following explanation, also in certain cases incorporation of one or more species contained in the ambient 220 into the surface areas 285 may also be a part of the interaction 286. In other cases, the interaction, in addition or alternatively to representing diffusion of a specific species, may involve exchange of energy, for instance, by heat conduction, convection and/or radiation, thereby also contributing to a change of status of the one or more substrates 284A, 284B, at least when considering the surface areas 285. That is, the status of the one or more substrates 284A, 284B may be determined on the basis of one or more parameter values associated with the surface areas 285, for instance, by determining a physical layer thickness thereof, and/or a material composition and/or an electrically equivalent layer thickness, as discussed above, an optical response of the surface 285, for instance by exposing at least a portion of the surface areas 285 to any type of radiation and detecting and analyzing reflected and/or scattered radiation from the surface areas 285, and the like. This status may be appropriately decoded into the information 235 supplied to the ambient control unit 230. In some illustrative embodiments, this information may be provided in advance without requiring a monitoring or determination of the respective status within the ambient 220. In this case, the information 235 may be received at the ambient control unit 230 and may be processed so as to identify values of at least one or more of the ambient-specific parameters 231-234 resulting in maintenance of the status of the one or more substrates 284A, 284B within specified limits.

In still other illustrative embodiments, the information 235 may include updated information 235A obtained from the ambient 220, for instance, on the basis of respective sensors (not shown) or any other measurement instruments provided within the system 200 so as to continuously, or at least regularly, obtain respective measurement results that may be fed to the control unit 230 as information 235A. In this case, a current, or at least a relatively current, status of the one or more substrates 284A, 284B may be obtained so as to allow the establishment of a feedback control loop on the basis of the one or more ambient-specific parameters 231-234 for maintaining the substrate status within a specific range. It should be appreciated that the information 235A representing the current status of the substrates 284A, 284B within the ambient 220 may also be obtained on the basis of any external measurement system, which may, for instance, have access to the ambient 220, for instance, by entering a probing beam of radiation and receiving a scattered or reflected beam, and/or by temporarily removing one or more of the substrates 284A, 284B and subjecting the one or more substrates to a measurement process in the external measurement tool and returning the substrates without undue delay. In still other illustrative embodiments, the status of the one or more substrates 284A, 284B may be detected on the basis of monitoring one or more of the parameters 231-234 or any other ambient-related metric, which may be correlated with the actual status of the substrates 284A, 284B. For example, if significant amounts of a species may diffuse into the ambient 220 emanating from the surface areas 285, a corresponding increase may be detected within the ambient 220. On the other hand, when a measureable amount of species may be incorporated into the surface areas 285, a respective reduction of the species may also be detected in the ambient 220 and may be used as a measure of the current status of the substrates 284A, 284B.

In still other illustrative embodiments, the information 235 may include information 235C supplied from an external source, such as a supervising control system, such as the control system 183, as previously discussed with reference to FIG. 1. For example, the supervising control system 183 may provide a process recipe or at least a corresponding metric that may enable the control unit 230 to establish a respective correlation between the process recipe or its metric and one or more of the ambient-specific parameters 231-234. Furthermore, the information 235C may include measurement data in any appropriate manner, for instance, in a substantially pre-processed manner, since respective measurement data may typically be received by the supervising control system 183 and may be analyzed for controlling the overall process flow in the respective manufacturing environment, such as the environment 180 as discussed above with reference to FIG. 1.

In still other illustrative embodiments, the information 235 may comprise measurement data 235D, which may be directly supplied by measurement tools 182 external to the system 200, such as the measurement tools 182A-182N of the manufacturing environment 180 of FIG. 1. It should be appreciated that the measurement data 235D may not necessarily directly refer to the current status of the substrates 284A, 284B, but may allow an assessment of the status on the basis of a corresponding model and the like, which may also be implemented in the control unit 230 and/or in the supervising control system 183.

Upon operating the system 200, substrates, such as the substrates 284A, 284B, may need to be temporarily stored, for instance, due to a planned or non-planned queue time and may be entered into the carrier 210, wherein, in some illustrative embodiments, as discussed above, the carrier 210 may, itself, be used as a transport container for transporting the substrates, even if a pronounced queue time is not necessary. To this end, the carrier 210 is appropriately equipped so as to receive at least one substrate and appropriately hold the substrate in position substantially without affecting respective micro-processed areas, such as the substrate areas 285. Prior to or upon arrival of the one or more substrates 284A, 284B within the carrier 210, the ambient 220 may be established on the basis of the information 235 and a control action by the control unit 230. To this end, the information may be evaluated with respect to the status of the one or more substrates 284A, 284B, for instance, by identifying a process recipe and the like, which may typically result in a specific range of values for the substrate status, such as an electrically equivalent thickness, as discussed above, wherein a certain variation of the status of several substrates may be present due to process variations of the previously performed processes, as also discussed above and in the context of FIG. 1. In relation to the determined status of the substrates 284A, 284B, the one or more ambient-specific parameters 231-234 may be adjusted to appropriate values so as to obtain the desired composition of the ambient 220. For example, a correlation may be established in advance for a specific process status and one or more ambient-specific parameters 231-234 in order to maintain the status within specified limits, at least for a predefined length of queue time.

For example, a correlation may have been established in order to correlate the diffusion activity of a species in the surface areas 285 with the partial pressure of one or more gaseous components in the ambient 220 in order to appropriately control the diffusion activity over a specific length of time. As previously discussed, in cases when a silicon oxide base material is treated so as to incorporate therein a nitrogen species, a given process recipe and thus a specific fraction of nitrogen species within the silicon oxide base material may result in out-diffusion of the nitrogen species when storing a substrate in a standard clean room atmosphere having approximately 20% oxygen and 80% nitrogen at standard pressure. On the other hand, for the same total pressure, a 100% nitrogen atmosphere may result in an increase of the nitrogen content in the surface areas 285, which is believed to be caused by diffusion of gaseous species into the surface areas 285. Irrespective of the mechanism involved for a given total pressure of the ambient 220, the nitrogen fraction may be controlled by adjusting the change of nitrogen content in the surface areas 285 so as to comply with predefined limits. For example, the nitrogen fraction in the ambient 220 may be controlled to be less than 100% and higher than 80% for a given total standard pressure of the ambient 220. It should be appreciated that, in addition to or alternatively to varying the partial pressure of one gaseous species, the total pressure, i.e., the partial pressure of all constituent gas species of the ambient 220, may be reduced or increased in equal proportion, thereby also affecting the interaction mechanism 286. It should be appreciated that controlling the fraction of one or more gaseous species in the ambient 220 may include both of the above-described mechanisms, i.e., individual control of the partial pressure of the one or more gaseous species and commonly increasing/reducing the fraction of any of the gaseous species in the ambient 220 with equal proportion.

In other illustrative embodiments, in addition to or alternatively to controlling the fraction of one or more gaseous species of the ambient 220, the temperature of the ambient 220 may be adjusted in order to influence the interaction mechanism 286. For instance, it is believed that a reduction of the temperature of the substrates 284A, 284B may also significantly reduce the diffusion activity from the surface areas 285 into the ambient 220 and vice versa, so that an initial fraction of the species within the surface areas 285 may be maintained without significant change over an extended length of time, compared to situations in which the substrates 284A, 284B are exposed to the standard clean room temperatures. To this end, temperature control may be established on the basis of direct contact with the substrates 284A, 284B by any appropriate heating/cooling unit (not shown), by convection via the gaseous atmosphere in the ambient 220 and/or by radiation heating/cooling. For example, when designing an interior surface of the carrier 210 as a surface having substantially a black body characteristic, i.e., having an emission/absorption coefficient of approximately 1, the substrates 284A, 284B may finally adopt substantially the same temperature as the interior surface of the carrier 210, even if the emission/absorption coefficient is moderately low and thermal conductivity and convection in the ambient 220 are also reduced.

As discussed above, based on additional information regarding the status of the substrates 284A, 284B, an even further enhanced control mechanism may be established. For instance, based on the information 235A, a feedback control mechanism may be established, thereby even further reducing the variability of the status of the substrates 284A, 284B substantially irrespective of the storage time in the ambient 220. Moreover, as already discussed above, control of the ambient 220 may also be used as a type of additional process control for establishing a specified status, for instance a specific status of a material layer, such as a dielectric material, a conductive material and the like, by controlling the ambient 220 so as to reduce the initial spread in the status of the substrates 284A, 284B upon entering the ambient 220 and controlling at least one of the ambient-specific parameters 231-234 so as to reduce the deviation of the current status with respect to a target value.

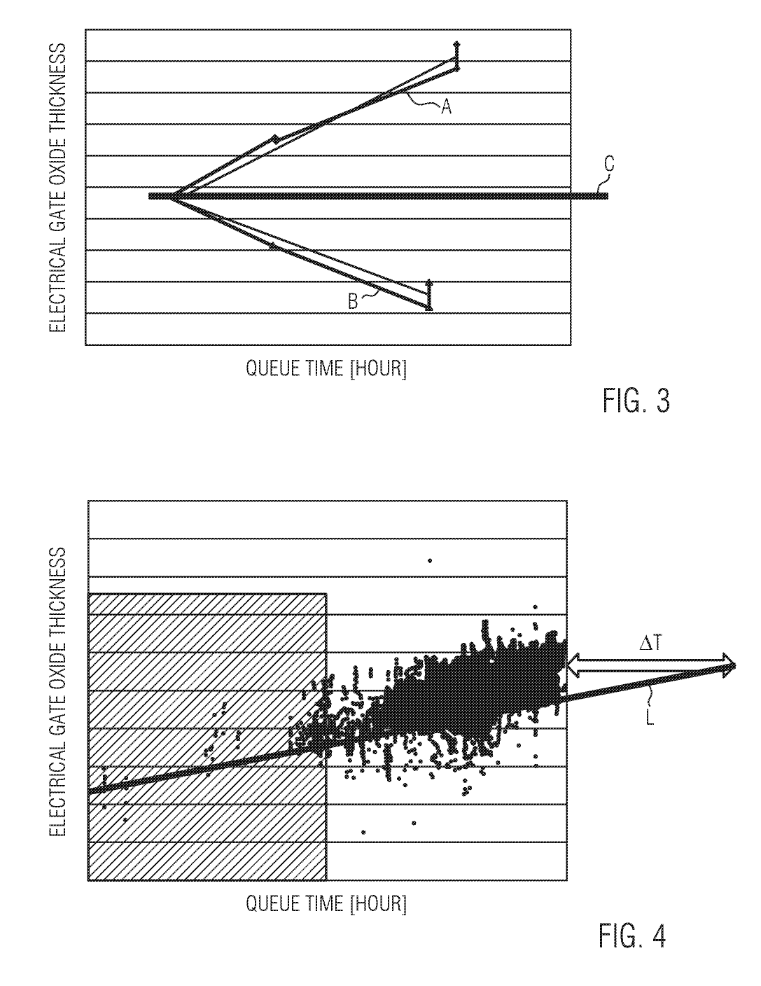

FIG. 3 schematically illustrates the variation of the status of substrates versus queue time when storing the substrate in different ambients. It should be appreciated that the vertical axis represents the status, which may be expressed as an electrically equivalent thickness of a gate dielectric layer having incorporated therein a nitrogen species, as discussed above, wherein, for this specific process recipe, an initial status or electrically equivalent thickness in the range of 20-25 Å (Ångstrom) may be assumed. Curve A represents the change of status over time when storing the respective substrates in a clean room atmosphere, i.e., at approximately 80% nitrogen and approximately 20% oxygen at a standard pressure of approximately 100 hPa. As is evident, after approximately 48 hours of queue time, a significant increase of the equivalent thickness may be observed. When considering other concepts, which may be frequently used upon storing micro-processed substrates by establishing a substantially inert atmosphere, such concepts may typically involve a purge on the basis of 100% nitrogen, which may also result in a significant change of status, however, this time in the other direction, i.e., reducing the equivalent thickness, as indicated by Curve B. As is evident, both strategies may exhibit a significant slope with respect to the change of status, thereby requiring an appropriately selected maximum queue time, for instance of approximately 10 hours or less, that must not be exceeded in order to maintain the corresponding devices within acceptable performance and quality ranges.

On the other hand, upon controlling the ambient 220 (FIG. 2) on the basis of the substrate status in order to reduce the slope of the status change and/or so as to control the status to a desired range, when a significant variability in the initial status may be detected, as previously discussed, a significantly prolonged queue time may become available, as indicated by Curve C, thereby also enhancing overall scheduling flexibility in a corresponding manufacturing environment, such as the environment 180 of FIG. 1. For example, Curve C may be obtained by controlling the contents of nitrogen in the ambient 220 of FIG. 2, for instance, by adjusting a corresponding fraction of nitrogen for a pressure corresponding to the pressure of the clean room to approximately 90% nitrogen and 10% oxygen. A corresponding appropriate parameter value for the nitrogen concentration may be established on the basis of experiments in advance, while, in other cases, a respective feedback control loop may be established when appropriate relatively current measurement data indicating the current status may be available, as discussed above. It should be appreciated that, in addition to or alternatively to the nitrogen partial pressure, one or more further ambient-specific parameters may be controlled, such as the total pressure of the gaseous atmosphere and/or the temperature of the ambient, which may also have a significant influence on the diffusion behavior of any species present in surface areas of the substrates under consideration.

FIG. 4 schematically illustrates a part of measurement data that represents the status of micro-processed substrates, which may comprise a nitrogen-containing silicon oxide-based dielectric material that is subject to out-diffusion upon storing the substrates during queue times in the standard clean room atmosphere, as already discussed above. For example, a status is indicated as the equivalent thickness of a gate dielectric layer of field effect transistors formed in polysilicon SiON technology, wherein the increase of the equivalent thickness with increasing queue time is illustrated. It should be appreciated that the horizontal axis, representing the queue time, is in a logarithmic scale, while the vertical axis, indicating the electrically equivalent gate oxide thickness, is linear and represented in A. Curve A is a linear fit indicating the slope of the change of the status with time, wherein, as discussed above, a certain maximum queue time may be allowable so as to maintain the resulting spread of the electrical equivalence gate oxide thickness within a specific range. For instance, a minimum queue time of 1 hour for accommodating any process related differences and a maximum queue time of 10 hours may typically be applied so as to maintain the spread in electrical gate oxide thickness within the allowed range. As indicated by Curve C, a corresponding control of one or more ambient-specific parameters when storing the respective substrates may significantly reduce the slope of the respective change of status, thereby obtaining a significantly prolonged queue time, indicated by ΔT, compared to the conventional strategy. Again, it should be appreciated that the time axis is logarithmic in scale, so that the interval ΔT represents a significant increase of acceptable queue time for a given tolerance range of substrate status, i.e., electrically equivalent thickness in this example. It should be appreciated that the increase of queue time may be obtained by affecting the diffusion mechanism on the basis of a reduced temperature compared to the usual temperature of the surrounding clean room, wherein the degree of temperature reduction may influence the resulting additional ΔT of the queue time. For example, a temperature reduction of approximately 10-20° C. with respect to the clean room temperature may be readily accomplished on the basis of convection cooling in the ambient 220 of FIG. 2.

It should be appreciated that reducing the diffusion activity by reducing the ambient temperature may also be combined with other mechanisms, such as controlling the content of one or more gaseous species of the ambient 220, as also discussed in the context of FIG. 3. On the other hand, diffusion activity may be increased, if considered appropriate, by increasing the temperature and/or radiation intensity of a specific portion of the electromagnetic spectrum within the ambient 220, thereby also providing an efficient mechanism for efficiently adjusting the target value of the status under consideration and also increasing a potential queue time for the substrates under consideration.

As a result, the present disclosure provides systems and techniques in which the status of micro-processed substrates may be controlled during transport and/or storage times, so as to stay within predefined limits, thereby also providing the possibility of increasing queue times of respective substrates without negatively affecting the device performance and quality due to undue variability of the status of substrates at various manufacturing stages. The option of increasing queue times may significantly contribute to superior flexibility in scheduling the manufacturing flow in complex manufacturing environments, since responding to any non-predictable events in the manufacturing environment may be managed on the basis of significantly relaxed queue time requirements. In addition to superior flexibility with respect to queue time violations, the control of the storage ambient with respect to a specified substrate status may provide additional control mechanisms for many types of processes, such as the formation of sensitive dielectric materials that may be subject to out-diffusion of specific species prior to a subsequent process. Moreover, respective strategies may also be applied to other sensitive processes, such as the formation of sophisticated gate dielectric materials including high-k dielectric components and metal-containing materials. Similarly, the formation of highly conductive metals in combination with sophisticated low-k dielectric materials may also involve processes which may be subject to a significant variation of substrate status during two sequential process steps. In these cases, the status-dependent control of ambient-specific parameters in an ambient for storing the substrates having a specific status may also be efficiently employed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A system for temporarily storing substrates during processing, the system comprising:
a carrier configured to receive and hold one or more substrates having a specific substrate status in a controllable ambient; and
an ambient control unit operatively connected to said carrier and configured to control said controllable ambient by adjusting one or more ambient specific parameters in relation to said specific substrate status.

2. The system of claim 1, wherein said specific substrate status corresponds to a processing state after having incorporated a species into surface areas of said one or more substrates and wherein said incorporated species is subject to diffusion out of said surface areas.

3. The system of claim 1, wherein said ambient control unit is configured to control, as said one or more specific ambient parameters, at least one of a gas composition and a temperature of said one or more substrates.

4. The system of claim 2, wherein said gaseous species comprise nitrogen and said surface areas correspond to oxide areas to be used as dielectric material of a capacitive structure.

5. The system of claim 4, wherein said ambient control unit is configured to control a nitrogen concentration to a value that is less than 100% and higher than 80%.

6. The system of claim 4, wherein said ambient control unit is configured to control an ambient temperature so as to adjust a substrate temperature of said one or more substrates to be lower than an environmental temperature outside said carrier.

7. The system of claim 1, wherein said carrier is a transport and storage container used in a semiconductor facility.

8. The system of claim 1, further comprising a sensor unit connected to said carrier and said ambient control unit so as to detect a physical quantity indicative of at least one of said one or more ambient parameters and to supply a sensor signal to said ambient control unit.

9. The system of claim 1, further comprising a communication unit operatively connected to said ambient control unit and being configured to receive information of said specific substrate status.

10. The system of claim 9, wherein said information includes measurement information regarding said specific substrate status.

11. A method, comprising
determining a substrate status of one or more substrates at a specified stage of processing said one or more substrates; and
adjusting at least one ambient parameter of a controllable ambient of said one or more substrates in relation to said substrate status.

12. The method of claim 11, wherein determining said substrate status comprises receiving information on said substrate status for at least one of said one or more substrates.

13. The method of claim 12, wherein said information is obtained on the basis of at least one of a process recipe applied during said micro-processing prior to determining said substrate status and measurement data obtained from one or more measurement substrates having experienced the same micro-processing as said one or more substrates.

14. The method of claim 11, wherein said at least one ambient parameter represents at least one of a temperature of said controllable ambient and a fraction of at least one gaseous species of said controllable ambient.

15. The method of claim 11, wherein said at least one ambient parameter represents an intensity distribution of radiation within said controllable ambient.

16. The method of claim 14, wherein determining said substrate status comprises determining a level of diffusion of a species from surface areas of said one or more substrates into an environment of specified temperature and gas composition.

17. The method of claim 16, wherein said environment of specified temperature and gas composition is said controllable ambient.

18. The method of claim 16, wherein adjusting at least one ambient parameter comprises adjusting at least one of a gas composition and a temperature of said controllable ambient so as to maintain said level of diffusion with a target range.

19. A system for controlling an ambient of processed substrates, said system comprising:
a substrate carrier configured to receive one or more of said processed substrates, said processed substrates comprising surface areas with a species subject to diffusion from said surface areas into an ambient confined by said substrate carrier; and
an ambient control unit configured to control said ambient by adjusting at least one ambient specific parameter of said ambient so as to maintain a level of diffusion of said species within a target range.

20. The system of claim 19, wherein said at least one ambient specific parameter corresponds to at least one of a gas composition of said ambient and a temperature of said ambient.
